(19) United States
(12) Patent Application Publication
(10) Pub. No.: US 2025/0359315 A1
(43) Pub. Date: Nov. 20, 2025

(54) INTEGRATED CIRCUIT HAVING TRANSISTORS WITH DIFFERENT WIDTH SOURCE AND DRAIN TERMINALS

(71) Applicants: TAIWAN SEMICONDUCTOR MANUFACTURING COMPANY, LTD., Hsinchu (TW); TSMC NANJING COMPANY, LIMITED, Nanjing (CN); TSMC CHINA COMPANY, LIMITED, Shanghai (CN)

(72) Inventors: XinYong WANG, Hsinchu (TW); Cun Cun CHEN, Hsinchu (TW); Ying HUANG, Hsinchu (TW); Chih-Liang CHEN, Hsinchu (TW); Li-Chun TIEN, Hsinchu (TW)

(21) Appl. No.: 19/288,772

(22) Filed: Aug. 1, 2025

Related U.S. Application Data
(63) Continuation of application No. 18/152,007, filed on Jan. 9, 2023.

(30) Foreign Application Priority Data
Sep. 9, 2022 (CN) 202211101953.8

(51) Int. Cl. H10D 84/85; H01L 23/522; H01L 23/528; H10D 84/01; H10D 84/03

(52) U.S. Cl. CPC H10D 84/85; H01L 23/5226; H01L 23/5286; H10D 84/0186; H10D 84/038

(57) ABSTRACT

A device includes: first and second power rails; first and second active regions; a first source/drain (S/D) conductor, wherein: the first S/D conductor is conductively connected to the first active region and the first power rail, and is in a layer between the first active region and the first power rail; a second S/D conductor, wherein: the second S/D conductor is at a same level as the first S/D conductor, the second S/D conductor is conductively connected to the first active region and is spaced apart from the first power rail, and the first S/D conductor is wider than the second S/D conductor; and a first gate between the first S/D conductor and the second S/D conductor, wherein: the first gate, the first S/D conductor, and the second S/D conductor are components of a first transistor at the first active region.

### PRIORITY CLAIM

The present application is a continuation of U.S. patent application Ser. No. 18/152,007, filed Jan. 9, 2023, which claims the priority of China Application No. 202211101953.8, filed Sep. 9, 2022, the disclosures of each of which are incorporated by reference herein their entireties.

### BACKGROUND

The recent trend in miniaturizing integrated circuits (ICs) has resulted in smaller devices which consume less power yet provide more functionality at higher speeds. The miniaturization process has also resulted in stricter design and manufacturing specifications as well as reliability challenges. Various electronic design automation (EDA) tools generate, optimize, and verify standard cell layout designs for integrated circuits while ensuring that the standard cell layout design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a layout diagram of an integrated circuit, in accordance with some embodiments.

FIG. 2 is a layout diagram of an array of terminal-conductors having the same pitch distance between adjacent terminal-conductors, in accordance with some embodiments.

FIG. 3 is a layout diagram of a circuit cell in an integrated circuit, in accordance with some embodiments.

FIG. 4A is a layout diagram of an inverter gate in a circuit cell, in accordance with

some embodiments.

FIGS. 4B-4C are cross-sectional views of the inverter gate in cutting planes as specified by FIG. 4A, in accordance with some embodiments.

FIG. 5A is a layout diagram of an inverter gate in a circuit cell, in accordance with some embodiments.

FIGS. 5B-5C are cross-sectional views of the inverter gate in cutting planes as specified by FIG. 5A, in accordance with some embodiments.

FIG. 6 is a layout diagram of a NAND gate in a circuit cell, in accordance with some embodiments.

FIG. 7 is a layout diagram of a NAND gate in a circuit cell, in accordance with some embodiments.

FIG. 8 is a flowchart of a method 800 of manufacturing an integrated circuit, in accordance with some embodiments.

FIG. 9 is a block diagram of an electronic design automation (EDA) system in accordance with some embodiments.

FIG. 10 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a circuit cell in the integrated circuit includes a transistor that has the channel region and the source/drain regions formed in an active-region structure. Examples of the active-region structure include a fin structure, a nano-sheet structure, or a nano-wire structure. In the circuit cell, a gate-conductor intersects the active-region structure at the channel region, a first terminal-conductor intersects the active-region structure at the source region, and a second terminal-conductor intersects the active-region structure at the drain region. In some embodiments, when the width of the first terminal-conductor is larger than the width of the second terminal-conductor, the speed performance of the circuit cell is improved, as compared with alternative implementations in which the widths of the first terminal-conductor and the second terminal-conductor are the same.

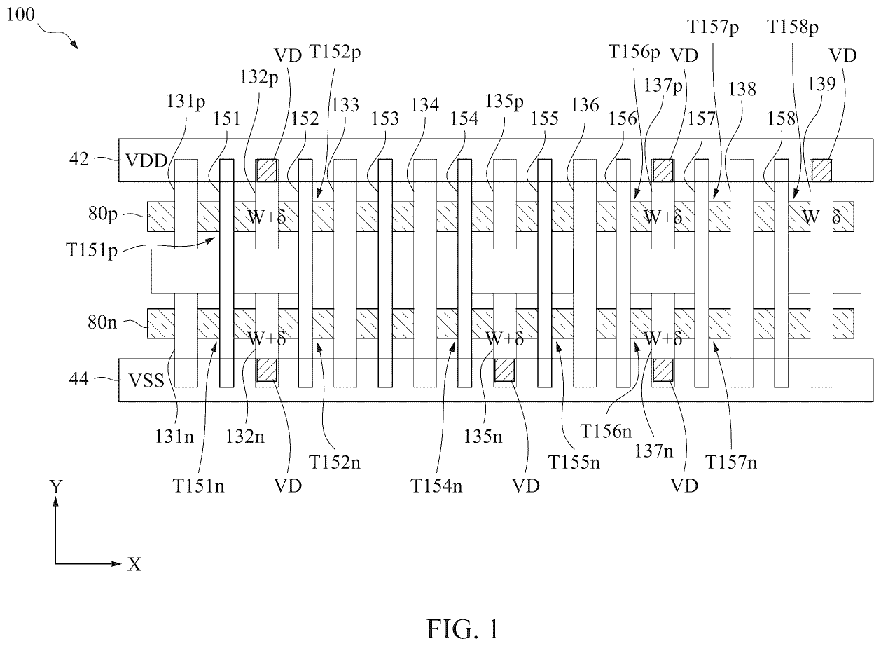

FIG. 1 is a layout diagram of an integrated circuit 100, in accordance with some embodiments. The layout diagram of FIG. 1 includes layout patterns extending in the Y-direction for specifying gate-conductors 151-158, and terminal-conductors (131p-132p, 131n-132n, 133-134, 135p, 135n, 136, 137p, 137n, and 138-139). The layout diagram of FIG. 1 also includes layout patterns extending in the X-direction for specifying active-region structures (80p and 80n), and power rails (42 and 44). The Y-direction is perpendicular to the X-direction.

In the integrated circuit 100 as specified by the layout diagram of FIG. 1, gate-conductors 151-158 intersect the active-region structure 80p at the channel region of various PMOS transistors and intersect the active-region structure 80n at the channel region of various NMOS transistors. In some embodiments, when the active-region structures 80p and 80n are formed with fin structures, the PMOS transistors formed in the active-region structures 80p and the NMOS transistors formed in the active-region structures 80n are FinFETs. In some embodiments, when the active-region structures 80p and 80n are formed with nano-sheet structures, the PMOS transistors formed in the active-region structures 80p and the NMOS transistors formed in the active-region structures 80n are nano-sheet transistors. In some embodiments, when the active-region structures 80p and 80n are formed with nano-wire structures, the PMOS transistors formed in the active-region structures 80p and the NMOS transistors formed in the active-region structures 80n are nano-wire transistors.

In the integrated circuit 100 as specified by the layout diagram of FIG. 1, some of the terminal-conductors intersect the active-region structure 80p at the source/drain regions of PMOS transistors and form the source/drain terminals for the corresponding PMOS transistors, while some of the terminal-conductors intersect the active-region structure 80n at the source/drain regions of NMOS transistors and form the source/drain terminals for the corresponding NMOS transistors. The terminal-conductors intersecting the active-region structure 80p include the terminal-conductors 131p-132p, 133-134, 135p, 136, 137p, and 138-139. The terminal-conductors intersecting the active-region structure 80n include the terminal-conductors 131n-132n, 133-134, 135n, 136, 137n, and 138-139.

In FIG. 1, some of the terminal-conductors have a first width W along the X-direction, while some of the terminal-conductors have a second width W+δ along the X-direction. The second width W+δ is larger than the first width W by a predetermined amount δ. The terminal-conductors having the first width W include 131p, 131n, 133-134, 135p, 136, and 138. The terminal-conductors having the second width W+δ include 132p, 132n, 135n, 137p, 137n, and 139. Each of the terminal-conductors 132p, 135p, 137p, and 139 intersects the power rail 42 and is connected to the power rail 42 through a corresponding via-connector VD. Each of the terminal-conductors 132n, 135n, and 137n intersects the power rail 44 and is connected to the power rail 44 through a corresponding via-connector VD. The power rail 42 is configured to provide an upper supply voltage VDD, while the power rail 44 is configured to provide a lower supply voltage VSS.

In FIG. 1, each of the terminal-conductors 132p, 137p, and 139 is a source terminal of at least one PMOS transistor. The terminal-conductor 132p is the source terminal of a PMOS transistor T151p and the source terminal of a PMOS transistor T152p. The PMOS transistor T151p has the channel region in the active-region structure 80p under the gate-conductor 151 and the PMOS transistor T152p has the channel region in the active-region structure 80p under the gate-conductor 152. The terminal-conductor 137p is the source terminal of a PMOS transistor T156p and the source terminal of a PMOS transistor T157p. The PMOS transistor T156p has the channel region in the active-region structure 80p under the gate-conductor 156 and the PMOS transistor T157p has the channel region in the active-region structure 80p under the gate-conductor 157. The terminal-conductor 139 is the source terminal of a PMOS transistor T158p having the channel region in the active-region structure 80p under the gate-conductor 158.

As compared with an alternative implementation in which each of the terminal-conductors 132p, 137p, and 139 has the first width W, increasing the width of each of the terminal-conductors 132p, 137p, and 139 to the second width W+δ reduces signal delays in the integrated circuit 100. When the width of a terminal-conductor (e.g., 132p, 137p, or 139) is increased, the resistance between the source terminal of a corresponding transistor (e.g., T151p, T152p, T156p, T157p, or T158p) and the power rail 42 is reduced, and the capacitance between the source terminal of a corresponding transistor (e.g., T151p, T152p, T156p, T157p, or T158p) and the signal ground is increased. Each of the power rails or conductors that is maintained at a constant voltage is a node of the signal ground.

In FIG. 1, each of the terminal-conductors 132n, 135n, and 137n, is a source terminal of at least one NMOS transistor. The terminal-conductor 132n is the source terminal of the NMOS transistor T151n and the source terminal of the NMOS transistor T152n. The NMOS transistor T151n has the channel region in the active-region structure 80n under the gate-conductor 151 and the NMOS transistor T152n has the channel region in the active-region structure 80n under the gate-conductor 152. The terminal-conductor 135n is the source terminal of the NMOS transistor T154n and the source terminal of the NMOS transistor T155n. The NMOS transistor T154n has the channel region in the active-region structure 80n under the gate-conductor 154 and the NMOS transistor T155n has the channel region in the active-region structure 80n under the gate-conductor 155. The terminal-conductor 137n is the source terminal of the NMOS transistor T156n and the source terminal of the NMOS transistor T157n. The NMOS transistor T156n has the channel region in the active-region structure 80n under the gate-conductor 156 and the NMOS transistor T157n has the channel region in the active-region structure 80n under the gate-conductor 157.

As compared with an alternative implementation in which each of the terminal-conductors 132n, 135n, and 137n has the first width W, increasing the width of each of the terminal-conductors 132n, 135n, and 137n to the second width W+δ reduces signal delays in the integrated circuit 100. When the width of a terminal-conductor (e.g., 132n, 135n, and 137n) is increased, the resistance between the source terminal of a corresponding transistor (e.g., T151n, T152n, T154n, T155n, T156n, or T157n) and the power rail 44 is reduced, and the capacitance between the source terminal of a corresponding transistor (e.g., T151n, T152n, T154n, T155n, T156n, or T157n) and the signal ground is increased.

In some embodiments, the pitch distance between adjacent terminal-conductors intersecting the active-region structure 80p is maintained at the same distance, even though some of the terminal-conductors intersecting the active-region structure 80p have the first width W and some of the terminal-conductors intersecting the active-region structure 80p have the second width W+δ. Similarly, the pitch distance between adjacent terminal-conductors intersecting the active-region structure 80n is maintained at the same distance, even though some of the terminal-conductors intersecting the active-region structure 80n have the first width W and some of the terminal-conductors intersecting the active-region structure 80n have the second width W+δ.

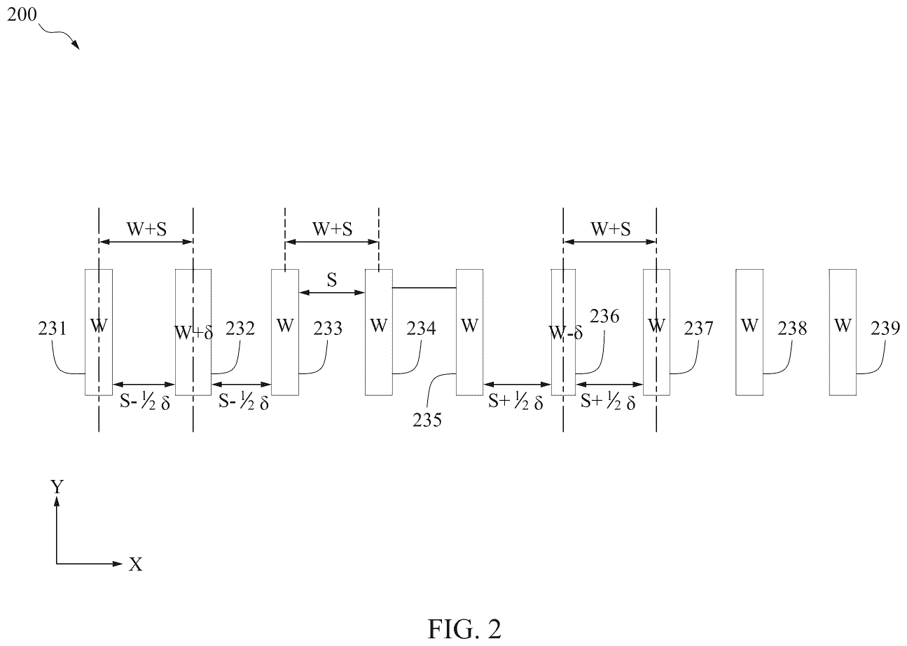

FIG. 2 is a layout diagram of an array 200 of terminal-conductors having the same pitch distance between adjacent terminal-conductors, in accordance with some embodiments. The array 200 of terminal-conductors includes terminal-conductors 231-239. Each of the terminal-conductors 231, 233-235, and 237-239 has the first width W, the terminal-conductor 232 has the second width W+δ, and the terminal-conductor 236 has the third width W−δ. The pitch distance between any pair of adjacent terminal-conductors in FIG. 2 is the same distance W+S. For example, while each of the terminal-conductors 233 and 234 has the first width W, the pitch distance between the terminal-conductors 233 and 234 is the distance W+S, because the edges of the terminal-conductors 233 and 234 are separated by the distance S. While the terminal-conductors 231 and 232 correspondingly have the first width W and the second width W+δ, the pitch distance between the terminal-conductors 231 and 232 is the distance W+S, because the edges of the terminal-conductors 231 and 232 are separated by the distance S−δ/2. While the terminal-conductors 236 and 237 correspondingly have the third width W−δ and the first width W, the pitch distance between the terminal-conductors 236 and 237 is the distance W+S, because the edges of the terminal-conductors 236 and 237 are separated by the distance S+δ/2.

In some embodiments, the second width W+δ is larger than the first width W by at least 20%. In some embodiments, the second width W+δ is larger than the first width W by at least 10%. In some embodiments, the first width W is larger than the third width W−δ by at least 20%. In some embodiments, the first width W is larger than the third width W−δ by at least 10%. In some embodiments, the second width W+δ is increased to a value without reducing the fabrication yield of the integrated circuit. When the second width W+δ is increased, the edge separation between a given terminal-conductor having the second width and one of the adjacent gate-conductor is decreased, which may increase the probability of unintentional shorting between the given terminal-conductor and the adjacent gate and consequently reduces the fabrication yield. In some embodiments, the third width W−δ is decreased to a value without reducing the fabrication yield of the integrated circuit. As the third width W−δ is decreased further, a given terminal-conductor may become too narrow, and the probability of forming an unintentional broken wire in the given terminal-conductor may increase, which consequently reduces the fabrication yield.

In some embodiments, the widths of some terminal-conductors in an integrated circuit are individually adjusted, whereby the performance of the integrated circuit is improved. In some embodiments, the width of at least one terminal-conductor is increased from the default width W, the width of at least one terminal-conductor is decreased from the default width W, and the widths of some terminal-conductors are maintained at the default width W.

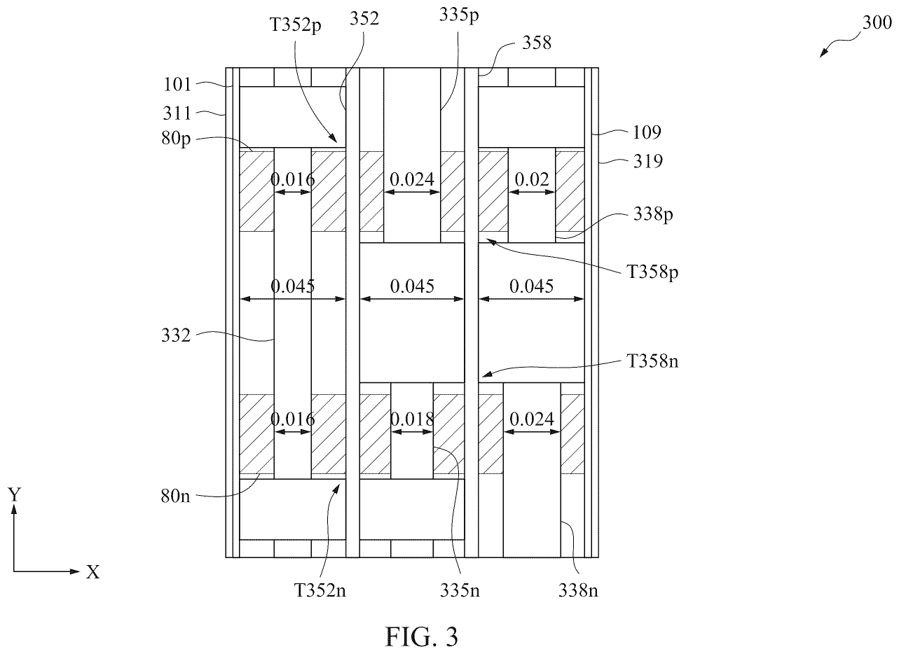

FIG. 3 is a layout diagram of a circuit cell 300 in an integrated circuit, in accordance with some embodiments. The layout diagram of FIG. 3 includes the layout patterns extending in the Y-direction for specifying gate-conductors (352 and 358), dummy gate-conductors (311 and 319) and terminal-conductors (332, 335p, 335n, 338p, and 338n). The layout diagram of FIG. 3 also includes the layout patterns extending in the X-direction for specifying active-region structures (80p and 80n) and power rails (42 and 44).

In the integrated circuit as specified by the layout diagram of FIG. 3, the gate-conductor 352 intersects the active-region structure 80p at the channel region of a PMOS transistor T352p and intersects the active-region structure 80n at the channel region of an NMOS transistor T352n. The gate-conductor 358 intersects the active-region structure 80p at the channel region of a PMOS transistor T358p and intersects the active-region structure 80n at the channel region of an NMOS transistor T358n. The dummy gate-conductors 311 and 319 at the vertical boundaries 101 and 109 of the circuit cell are not implemented as gate terminals of PMOS or NMOS transistors.

The terminal-conductor 332 intersects the active-region structure 80p at the drain region of the PMOS transistors T352p and intersects the active-region structure 80n at the drain region of an NMOS transistor T352n. The terminal-conductor 335p intersects the active-region structure 80p at the source regions of the PMOS transistors T352p and T358p. The terminal-conductor 338p intersects the active-region structure 80p at the drain regions of the PMOS transistor T358p. The terminal-conductor 335n intersects the active-region structure 80n at the source region of the NMOS transistors T352n and the drain region of the NMOS transistors T358n. The terminal-conductor 338n intersects the active-region structure 80n at the source region of the NMOS transistor T358n.

In FIG. 3, the numerical values of the widths of the terminal-conductors and the numerical values of the separations between the gate-conductors are labeled. Because of the layout design of FIG. 3 is provided as an example and the dimensions in the layout design are proportionally scalable, the numerical values for the widths and the separations are provided in an arbitrary unit (a.u.). For example, the separation between gate-conductors 352 and 358 is labeled 0.045 in a.u. When the arbitrary unit (a.u.) is selected to be 1000 nanometer, the separation between gate-conductors 352 and 358 is 45 nanometer. When the arbitrary unit (a.u.) is selected to be 2000 nanometer, the separation between gate-conductors 352 and 358 is 90 nanometer. When the arbitrary unit (a.u.) is selected to be 500 nanometer, the separation between gate-conductors 352 and 358 is 22.5 nanometer.

In FIG. 3, the terminal-conductor 335p functions as the source terminal of the PMOS transistors T352p and T358p, and the terminal-conductor 338n functions as the source terminal of the NMOS transistor T358n. The width of each of the terminal-conductors 335p and 338n is implemented as 0.024 a.u., which is larger than the width of any other terminal-conductor in the circuit cell of FIG. 3. Specifically, the width of the terminal-conductor 332 is 0.016 a.u., the width of the terminal-conductor 338p is 0.020 a.u., and the width of the terminal-conductor 335n is 0.018 a.u. In some embodiments, when the widths of the terminal-conductors that function as source terminals are increased and the widths of the terminal-conductors that function as drain terminals are decreased, the speed performance of the cell circuit is improved. In some embodiments, however, the width of the terminal-conductor 335p or 338n is increased to a value without reducing the fabrication yield of the integrated circuit having one or more circuit cells 300. When the width of the terminal-conductor 335p or 338n is increased, the edge separation between an adjacent gate-conductor (e.g., the gate-conductor 352 or 358) and the terminal-conductor 335p or 338n is decreased, which may increase the probability of unintentional shorting between the gate-conductor and the terminal-conductor 335p or 338n and consequently influence the fabrication yield. Similarly, in some embodiments, the width of the terminal-conductor 332 is decreased to a value without reducing the fabrication yield of the integrated circuit having one or more circuit cells 300. When the width of the terminal-conductor 332 is decreased and becomes too narrow, the probability of having an unintentional broken wire in the terminal-conductor 332 may increase and consequently influence the fabrication yield.

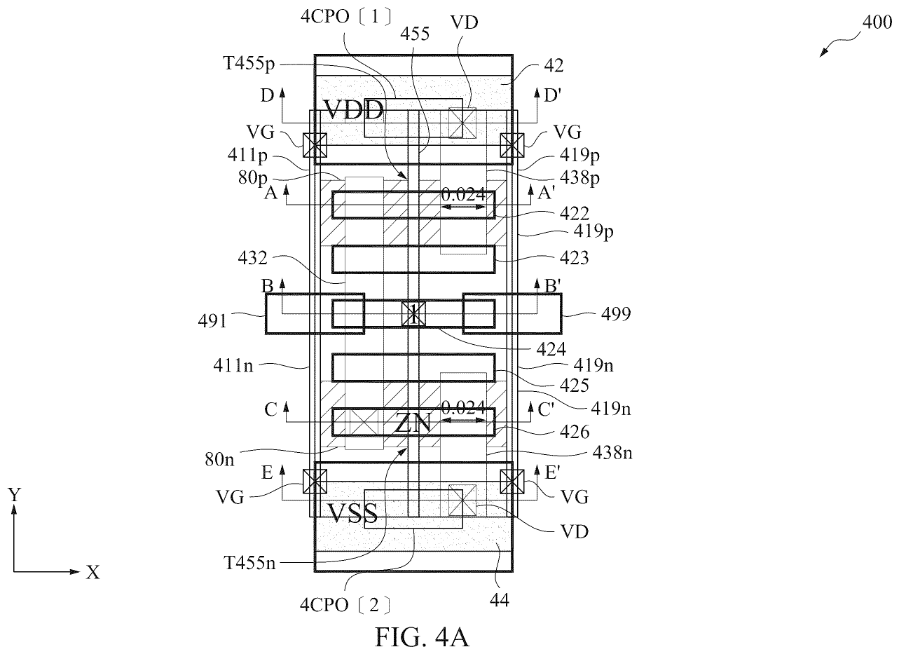

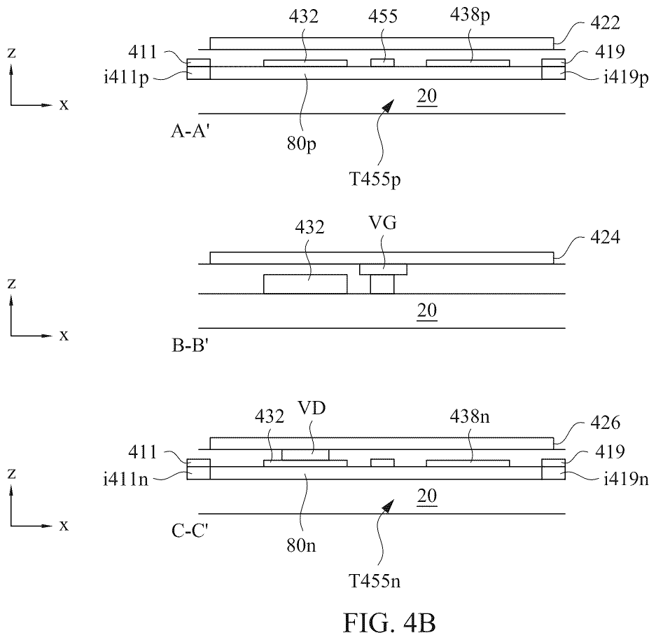

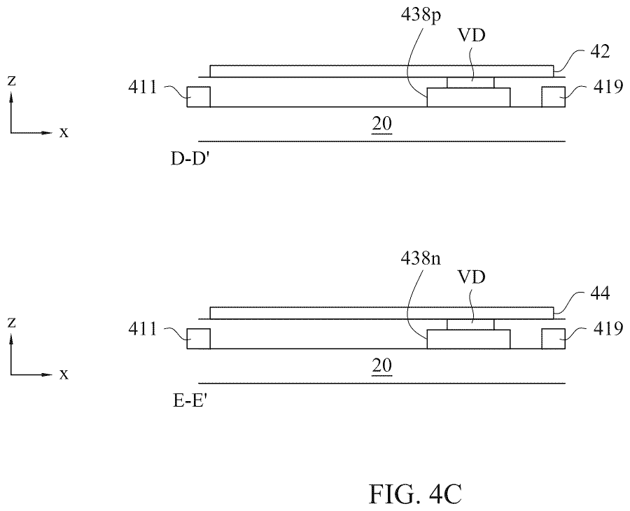

FIG. 4A is a layout diagram of an inverter gate 400 in a circuit cell, in accordance with some embodiments. The layout diagram of FIG. 4A includes the layout patterns extending in the Y-direction for specifying gate-conductor 455, dummy gate-conductors (411p, 411n, 419p, and 419n) and terminal-conductors (432, 438p, and 438n). The layout diagram of FIG. 4A also includes the layout patterns extending in the X-direction for specifying active-region structures (80p and 80n), horizontal conducting lines (422, 424, and 426) in a first metal layer, and power rails (42 and 44).

In the inverter gate 400 as specified by the layout diagram of FIG. 4A, the gate-conductor 455 intersects the active-region structure 80p at the channel region of a PMOS transistor T455p and intersects the active-region structure 80n at the channel region of an NMOS transistor T455n. The dummy gate-conductors 411p and 411n at a first vertical boundary of the circuit cell for the inverter gate 400 are separated from each other as specified by the cut gate layout pattern 491. The dummy gate-conductors 419p and 419n at a second vertical boundary of the circuit cell for the inverter gate 400 are separated from each other as specified by the cut gate layout pattern 499. Each of the dummy gate-conductors 411p and 419p is connected to the power rail 42 through a corresponding via-connector VG. Each of the dummy gate-conductors 411n and 419n is connected to the power rail 44 through a corresponding via-connector VG.

The terminal-conductor 432 intersects the active-region structure 80p at the drain region of the PMOS transistor T455p and intersects the active-region structure 80n at the drain region of an NMOS transistor T455n. The terminal-conductor 438p intersects the active-region structure 80p at the source region of the PMOS transistor T455p and connects to the power rail 42. In some embodiments, the terminal-conductor 438p is connected to the power rail 42 through a via-connector. The terminal-conductor 438n intersects the active-region structure 80n at the source region of the NMOS transistor T455n and connects to the power rail 44. In some embodiments, the terminal-conductor 438n is connected to the power rail 44 through a via-connector.

The horizontal conducting line 424 is connected to the gate-conductor 455 through a via-connector VG and functions as a pin connector for the input signal of the inverter gate 400. The horizontal conducting line 426 is connected to the terminal-conductor 432 through a via-connector VD and functions as a pin connector for the output signal “ZN” of the inverter gate 400.

FIG. 4B is cross-sectional views of the inverter gate 400 in cutting planes A-A′, B-B′, and C-C′ as specified by FIG. 4A, in accordance with some embodiments. In the cross-sectional view of the cutting plane A-A′ as shown in FIG. 4B, the active-region structure 80p is on the substrate 20. The gate-conductor 455 intersects the active-region structure 80p at the channel region of the PMOS transistor T455p. The terminal-conductors 432 and 438p intersect the active-region structure 80p correspondingly at the drain region and the source region of the PMOS transistor T455p. In some embodiments, the active regions (such as, the source region, the channel region, or the drain region) in the active-region structure 80p are isolated from the active regions in the adjacent cells by the boundary isolation region i411p under the dummy gate-conductor 411 and the boundary isolation region i419p under the dummy gate-conductor 419. The horizontal conducting line 422 is in the first metal layer overlying the interlayer dielectric that covers the gate-conductor 455 and the terminal-conductors 432 and 438p.

In the cross-sectional view of the cutting plane B-B′ as shown in FIG. 4B, the gate-conductor 455 and the terminal-conductors 432 are supported by the substrate 20. The horizontal conducting line 424 is in the first metal layer overlying the interlayer dielectric that covers the gate-conductor 455 and the terminal-conductor 432. The horizontal conducting line 424 is connected to the gate-conductor 455 through the via-connector VG.

In the cross-sectional view of the cutting plane C-C′ as shown in FIG. 4B, the active-region structure 80n is on the substrate 20. The gate-conductor 455 intersects the active-region structure 80n at the channel region of the NMOS transistor T455n. The terminal-conductors 432 and 438n intersect the active-region structure 80n correspondingly at the drain region and the source region of the NMOS transistor T455n. In some embodiments, the active regions (such as, the source region, the channel region, or the drain region) in the active-region structure 80n are isolated from the active regions in the adjacent cells by the boundary isolation region i411n under the dummy gate-conductor 411 and the boundary isolation region i419n under the dummy gate-conductor 419. The horizontal conducting line 426 is in the first metal layer overlying the interlayer dielectric that covers the gate-conductor 455 and the terminal-conductors 432 and 438n. The horizontal conducting line 426 is connected to the terminal-conductor 432 through the via-connector VD.

FIG. 4C is cross-sectional views of the inverter gate 400 in cutting planes D-D′ and E-E′ as specified by FIG. 4A, in accordance with some embodiments. As shown in the cross-sectional view of the cutting plane D-D′, the power rail 42 is conductively connected to the terminal-conductor 438p through a corresponding via-connector VD. As shown in the cross-sectional view of the cutting plane E-E′, the power rail 44 is also conductively connected to the terminal-conductor 438n through a corresponding via-connector VD.

In FIG. 4C, the gate-conductor 455 and the terminal-conductor 432 are absence in the cutting plane D-D′ and the cutting plane E-E′, based on the layout designs in FIG. 4A. In the layout diagram of FIG. 4A, the gate-conductor 455 extending in the positive Y-direction is terminated before reaching the cutting plane D-D′, as specified by the cut-gate pattern 4CPO[1], while the terminal-conductor 432 extending in the positive Y-direction does not reach the cutting plane D-D′. Additionally, the gate-conductor 455 extending in the negative Y-direction is terminated before reaching the cutting plane E-E′, as specified by the cut-gate pattern 4CPO[2], while the terminal-conductor 432 extending in the negative Y-direction does not reach the cutting plane E-E′.

In FIGS. 4A-4C, because the terminal-conductors 438p and 438n are source terminals of transistors, the widths of the terminal-conductors 438p and 438n are implemented to be larger than the width of the terminal-conductor 432, whereby the speed performance of the inverter gate 400 is improved. In one example, the width of each of the terminal-conductors 438p and 438n is 0.024 micrometer, and the width of the terminal-conductor 432 is smaller than 0.024 micrometer by a predetermined amount (e.g., by 0.008 micrometer).

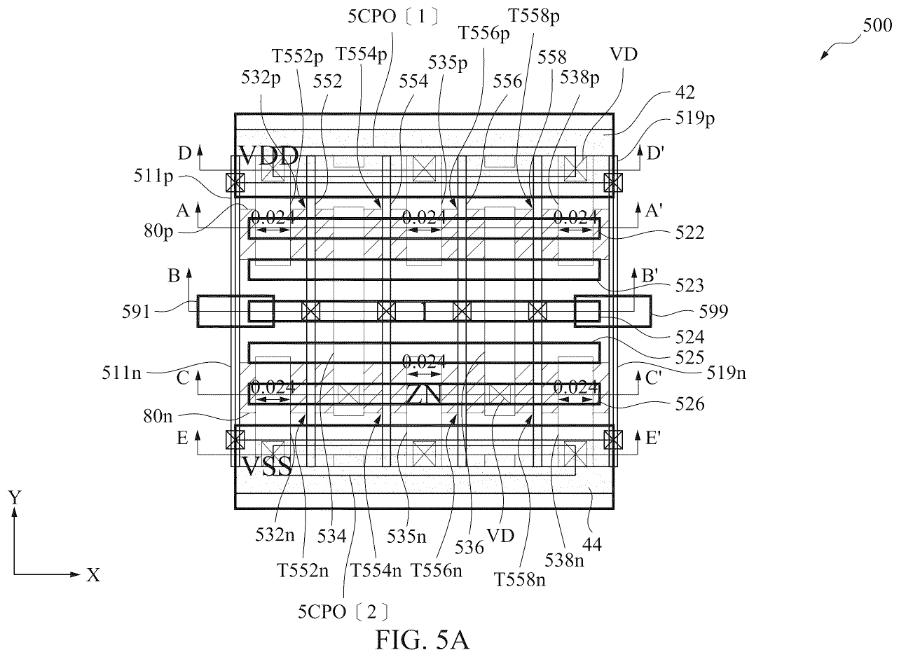

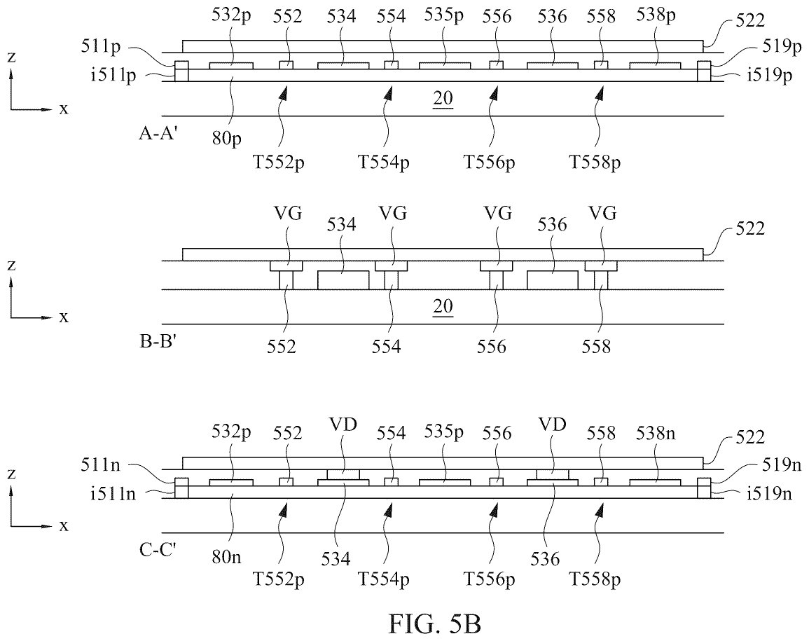

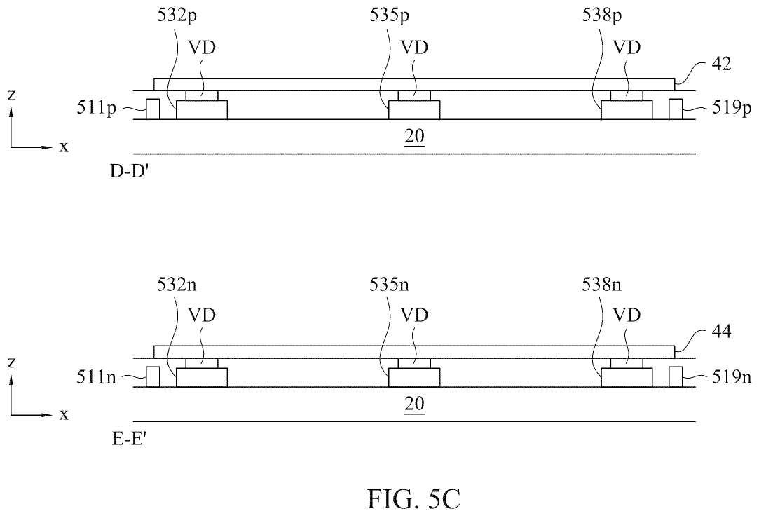

FIG. 5A is a layout diagram of an inverter gate 500 in a circuit cell, in accordance with some embodiments. The layout diagram of FIG. 5A includes the layout patterns extending in the Y-direction for specifying gate-conductors (552, 554, 556, and 558), dummy gate-conductors (511p, 511n, 519p, and 519n), and terminal-conductors (532p, 535p, 538p, 532n, 535n, 538n, 534, and 536). The layout diagram of FIG. 5A also includes the layout patterns extending in the X-direction for specifying active-region structures (80p and 80n), horizontal conducting lines (522-526) in a first metal layer, and power rails (42 and 44).

In the inverter gate 500 as specified by the layout diagram of FIG. 5A, each of the gate-conductors 552, 554, 556, and 558 intersects the active-region structure 80p correspondingly at the channel region of one of the PMOS transistors T552p, T554p, T556p, and T558p. Each of the gate-conductors 552, 554, 556, and 558 also intersects the active-region structure 80n correspondingly at the channel region of one of the NMOS transistors T552n, T554n, T556n, and T558n. The dummy gate-conductors 511p and 511n at a first vertical boundary of the circuit cell for the inverter gate 500 are separated from each other as specified by a cut gate layout pattern 591. The dummy gate-conductors 519p and 519n at a second vertical boundary of the circuit cell for the inverter gate 500 are separated from each other as specified by a cut gate layout pattern 599. Each of the dummy gate-conductors 511p and 519p is connected to the power rail 42 through a corresponding via-connector VG. Each of the dummy gate-conductors 511n and 519n is connected to the power rail 44 through a corresponding via-connector VG.

Each of terminal-conductors 532p, 535p, and 538p intersects the active-region structure 80p correspondingly at the source region of at least one of the PMOS transistors T552p, T554p, T556p, and T558p. Each of terminal-conductors 532p, 535p, and 538p is also connected to the power rail 42. Each of terminal-conductors 532n, 535n, and 538n intersects the active-region structure 80n correspondingly at the source region of at least one of the NMOS transistors T552n, T554n, T556n, and T558n. Each of terminal-conductors 532n, 535n, and 538n is also connected to the power rail 44. The terminal-conductor 534 intersects the active-region structure 80p at the drain regions of the PMOS transistors T552p and T554p and intersects the active-region structure 80n at the drain regions of the NMOS transistors T552n and T554n. The terminal-conductor 536 intersects the active-region structure 80p at the drain regions of the PMOS transistors T556p and T558p and intersects the active-region structure 80n at the drain regions of the NMOS transistors T556n and T558n.

The horizontal conducting line 524 is connected to each of the gate-conductors 552, 554, 556, and 558 through a corresponding via-connector VG and functions as a pin connector for the input signal of the inverter gate 500. The horizontal conducting line 526 is connected to each of the terminal-conductors 534 and 536 through a corresponding via-connector VD and functions as a pin connector for the output signal “ZN” of the inverter gate 500. The inverter gate 500 includes four PMOS transistors T552p, T554p, T556p, and T558p and four NMOS transistors T552n, T554n, T556n, and T558n. The gate terminals of the four PMOS transistors and the four NMOS transistors are all connected together as the input node for the inverter gate 500. The drain terminals of the four PMOS transistors and the four NMOS transistors are all connected together as the output node for the inverter gate 500.

FIG. 5B is cross-sectional views of the inverter gate 500 in cutting planes A-A′, B-B′, and C-C′ as specified by FIG. 5A, in accordance with some embodiments. In the cross-sectional view of the cutting plane A-A′ as shown in FIG. 5B, the active-region structure 80p is on the substrate 20. Each of the gate-conductors 552, 554, 556, and 558 intersects the active-region structure 80p at a channel region of one of the PMOS transistors T552p, T554p, T556p, and T558p. Each of terminal-conductors 532p, 534, 535p, 534, and 538p intersects the active-region structure 80p at a source/drain region of at least one of the PMOS transistors T552p, T554p, T556p, and T558p. In some embodiments, the active regions of the inverter gate 500 in the active-region structure 80p are isolated from the active regions in the adjacent cells by the boundary isolation region i511p under the dummy gate-conductor 511 and the boundary isolation region i519p under the dummy gate-conductor 519. The horizontal conducting line 522 is in the first metal layer overlying the interlayer dielectric that covers the gate-conductors and the terminal-conductors.

In the cross-sectional view of the cutting plane B-B′ as shown in FIG. 5B, the gate-conductors 552, 554, 556, and 558 and the terminal-conductors 534 and 536 are supported by the substrate 20. The horizontal conducting line 524 is in the first metal layer overlying the interlayer dielectric that covers the gate-conductors 552, 554, 556, and 558 and the terminal-conductors 534 and 536. The horizontal conducting line 524 is connected to each of gate-conductors 552, 554, 556, and 558 through a via-connector VG.

In the cross-sectional view of the cutting plane C-C′ as shown in FIG. 5B, the active-region structure 80n is on the substrate 20. Each of the gate-conductors 552, 554, 556, and 558 intersects the active-region structure 80n at a channel region of one of the NMOS transistors T552n, T554n, T556n, and T558n. Each of terminal-conductors 532n, 534, 535n, 534, and 538n intersects the active-region structure 80n at a source/drain region of at least one of the NMOS transistors T552n, T554n, T556n, and T558n. In some embodiments, the active regions of the inverter gate 500 in the active-region structure 80n are isolated from the active regions in the adjacent cells by the boundary isolation region i511n under the dummy gate-conductor 511 and the boundary isolation region i519n under the dummy gate-conductor 519. The horizontal conducting line 526 is in the first metal layer overlying the interlayer dielectric that covers the gate-conductors and the terminal-conductors. The horizontal conducting line 526 is connected to each of the terminal-conductors 534 and 534 through a via-connector VD.

FIG. 5C is cross-sectional views of the inverter gate 500 in cutting planes D-D′ and E-E′ as specified by FIG. 5A, in accordance with some embodiments. As shown in the cross-sectional view of the cutting plane D-D′, the power rail 42 is conductively connected to each of the terminal-conductors 532p, 535p, and 538p through a corresponding via-connector VD. As shown in the cross-sectional view of the cutting plane E-E′, the power rail 44 is conductively connected to each of the terminal-conductors 532n, 535n, and 538n through a corresponding via-connector VD.

In FIG. 5C, the gate-conductors 552, 554, 556, and 558 and the terminal-conductors 534 and 536 are absence in the cutting plane D-D′ and the cutting plane E-E′, based on the layout designs in FIG. 5A. In the layout diagram of FIG. 5A, the gate-conductors 552, 554, 556 extending in the Y-direction is terminated before reaching the cutting plane D-D′ or the cutting plane E-E′, as specified by the cut-gate pattern 5CPO[1] and the cut-gate pattern 5CPO[2], while none of the terminal-conductors 534 and 536 extending in the Y-direction reaches the cutting plane D-D′ or the cutting plane E-E′.

In FIGS. 5A-5C, because the terminal-conductors 532p, 535p, and 538p are source terminals of the PMOS transistors and the terminal-conductors 532n, 535n, and 538n are source terminals of the NMOS transistors, the widths of the terminal-conductors 532p, 535p, and 538p and the widths of the terminal-conductors 532n, 535n, and 538n are implemented to be larger than the widths of the terminal-conductors 534 and 536, whereby the speed performance of the inverter gate 500 is improved.

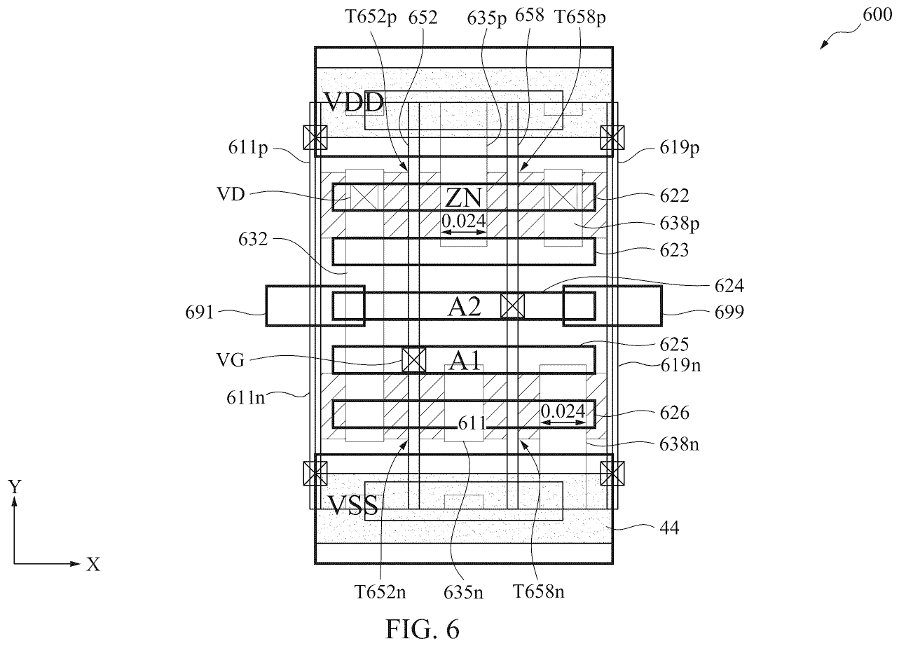

FIG. 6 is a layout diagram of a NAND gate 600 in a circuit cell, in accordance with some embodiments. The layout diagram of FIG. 6 includes the layout patterns extending in the Y-direction for specifying gate-conductors (652 and 658), dummy gate-conductors (611p, 611n, 619p, and 619n), and terminal-conductors (632, 635p, 635n, 638p, and 638n). The layout diagram of FIG. 6 also includes the layout patterns extending in the X-direction for specifying active-region structures (80p and 80n), horizontal conducting lines (622-626) in a first metal layer, and power rails (42 and 44).

In the integrated circuit as specified by the layout diagram of FIG. 6, the gate-conductor 652 intersects the active-region structure 80p at the channel region of a PMOS transistor T652p and intersects the active-region structure 80n at the channel region of an NMOS transistor T652n. The gate-conductor 658 intersects the active-region structure 80p at the channel region of a PMOS transistor T658p and intersects the active-region structure 80n at the channel region of an NMOS transistor T658n. The dummy gate-conductors 611p and 611n at a first vertical boundary of the circuit cell for NAND gate 600 are separated from each other as specified by the cut gate layout pattern 691. The dummy gate-conductors 619p and 619n at a second vertical boundary of the circuit cell for the NAND gate 600 are separated from each other as specified by the cut gate layout pattern 699. Each of the dummy gate-conductors 611p and 619p is connected to the power rail 42 through a corresponding via-connector VG. Each of the dummy gate-conductors 611n and 619n is connected to the power rail 44 through a corresponding via-connector VG.

The terminal-conductor 632 intersects the active-region structure 80p at the drain region of the PMOS transistor T652p and intersects the active-region structure 80n at the drain region of an NMOS transistor T652n. The terminal-conductor 635p intersects the active-region structure 80p at the source regions of the PMOS transistors T652p and T658p and is connected to the power rail 42. In some embodiments, the terminal-conductor 635p is connected to the power rail 42 through a via-connector. The terminal-conductor 638p intersects the active-region structure 80p at the drain regions of the PMOS transistor T658p. The terminal-conductor 635n intersects the active-region structure 80n at the source region of the NMOS transistor T652n and the drain region of the NMOS transistor T658n. The terminal-conductor 638n intersects the active-region structure 80n at the source region of the NMOS transistor T658n is connected to the power rail 44. In some embodiments, the terminal-conductor 638n is connected to and the power rail 44 through a via-connector.

The horizontal conducting line 625 is connected to the gate-conductors 652 through a corresponding via-connector VG and functions as a pin connector for the input signal A1 of the NAND gate 600. The horizontal conducting line 624 is connected to the gate-conductors 658 through a corresponding via-connector VG and functions as a pin connector for the input signal A2 of the NAND gate 600. The horizontal conducting line 622 is connected to each of the terminal-conductors 632 and 638 through a corresponding via-connector VD and functions as a pin connector for the output signal ZN of NAND gate 600.

The NAND gate 600 includes two PMOS transistors T652p and T658p having source/drain terminals connected parallelly between the power rail 42 and the horizontal conducting line 622. The NAND gate 600 includes two NMOS transistors T652n and T658n having source/drain terminals connected in series between the horizontal conducting line 622 and the power rail 44.

In FIG. 6, because the terminal-conductor 635p is the source terminal of the PMOS transistors T652p and T658p and the terminal-conductor 638n is the source terminal of the NMOS transistor T658n, the widths of the terminal-conductors 635p and 638n are implemented to be larger than the widths of the terminal-conductors 632, 635n, and 638p, whereby the speed performance of the NAND gate 600 is improved.

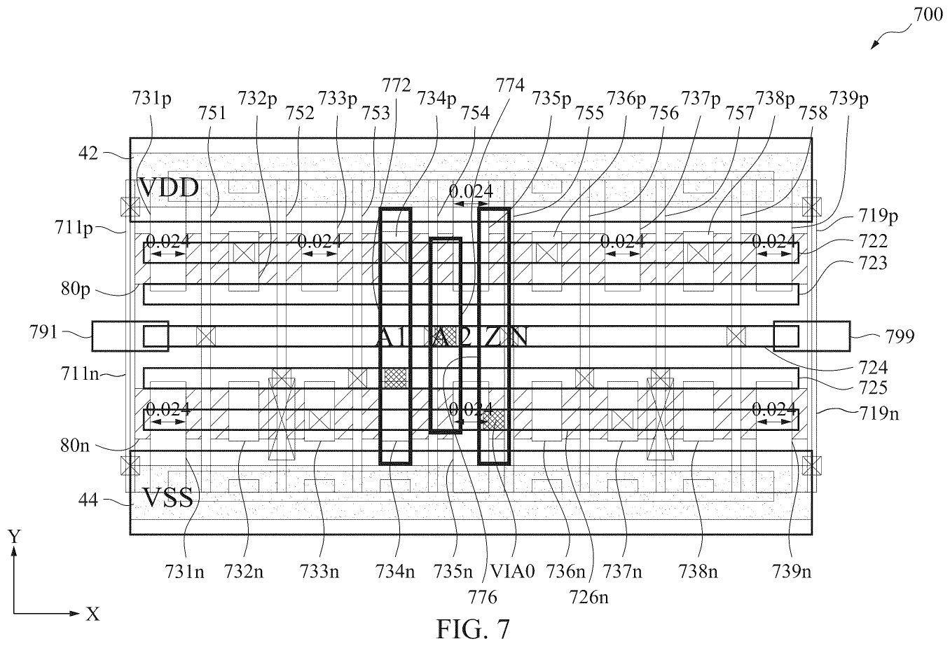

FIG. 7 is a layout diagram of a NAND gate 700 in a circuit cell, in accordance with some embodiments. The layout diagram of FIG. 7 includes the layout patterns extending in the Y-direction for specifying gate-conductors (751-758), dummy gate-conductors (711p, 711n, 719p, and 719n), and terminal-conductors (731p-739p and 731n-739n). The layout diagram of FIG. 7 also includes the layout patterns extending in the X-direction for specifying active-region structures (80p and 80n), horizontal conducting lines (722-726) in a first metal layer, and power rails (42 and 44). The layout diagram of FIG. 7 also includes the layout patterns extending in the Y-direction for specifying vertical conducting lines (772, 774, and 776) in a second metal layer which is isolated from the first metal layer by one or more layer of interlayer dielectric.

In the NAND gate 700 as specified by the layout diagram of FIG. 7, each of the gate-conductors 751-758 intersects the active-region structure 80p correspondingly at the channel region of respective PMOS transistors and intersects the active-region structure 80n correspondingly at the channel region of one of respective NMOS transistors. The dummy gate-conductors 711p and 711n at a first vertical boundary of the circuit cell for the NAND gate 700 are separated from each other as specified by a cut gate layout pattern 791. The dummy gate-conductors 719p and 719n at a second vertical boundary of the circuit cell for the NAND gate 700 are separated from each other as specified by a cut gate layout pattern 799. Each of the dummy gate-conductors 711p and 719p is connected to the power rail 42 through a corresponding via-connector VG. Each of the dummy gate-conductors 711n and 719n is connected to the power rail 44 through a corresponding via-connector VG.

The terminal-conductors 731p, 733p, 735p, 737p, and 739p intersect the active-region structure 80p correspondingly at the source regions of PMOS transistors. The terminal-conductors 731p, 733p, 735p, 737p and 739p are also connected to the power rail 42. The terminal-conductors 732p, 734p, 736p, and 738p intersect the active-region structure 80p correspondingly at the drain regions of PMOS transistors. Each of the terminal-conductors 732p, 734p, 736p, and 738p is also connected to the horizontal conducting line 722 through a corresponding via-connector VD.

The terminal-conductors 731n, 735n, and 739n intersect the active-region structure 80p correspondingly at the source regions of NMOS transistors. The terminal-conductors 731n, 735n, and 739n are also connected to the power rail 44. The terminal-conductors 733n and 737n intersect the active-region structure 80p correspondingly at the drain regions of NMOS transistors. Each of the terminal-conductors 733n and 737n is also connected to the horizontal conducting line 726 through a corresponding via-connector VD. The terminal-conductors 732n, 734n, 736n, and 738n intersect the active-region structure 80n correspondingly at the source/drain regions of NMOS transistors.

In FIG. 7, eight PMOS transistors are connected in parallel (with the source/drain terminals) between the power rail 42 and the horizontal conducting line 722. The eight NMOS transistors are grouped into four pairs of NMOS transistors. The two NMOS transistors in each pair of the NMOS transistors are connected in series (with the source/drain terminals) between the horizontal conducting line 726 and the power rail 44. When each of the horizontal conducting lines 722 and 726 is connected to the vertical conducting line 776 through a corresponding via-connector VIA0, the drain terminals of PMOS transistors are connected to the drain terminals of NMOS transistors.

The horizontal conducting line 724 is connected to each of the gate-conductors 751, 754, 755, and 758 through a corresponding via-connector VG and functions as a pin connector for the input signal “A2” of the NAND gate 700. When the vertical conducting line 774 is connected to the horizontal conducting line 724 through a via connector VIA0, the vertical conducting line 774 is configured to carry the input signal A2. The horizontal conducting line 725 is connected to each of the gate-conductors 752, 753, 756, and 757 through a corresponding via-connector VG and functions as a pin connector for the input signal A1 of the NAND gate 700. When the vertical conducting line 772 is connected to the horizontal conducting line 725 through a via connector VIA0, the vertical conducting line 772 is configured to carry the input signal A1. Furthermore, as the vertical conducting line 776 is connected to each of the horizontal conducting lines 722 and 726 through a via connector VIA0, the vertical conducting line 776 is configured to carry the output signal ZN of the NAND gate 700.

In FIG. 7, because the terminal-conductors 731p, 733p, 735p, 737p and 739p are source terminals of the PMOS transistors connecting to the power rail 42 and the terminal-conductors 731n, 735n, and 739n are source terminals of the NMOS transistors connecting to the power rail 44, the widths of the terminal-conductors 731p, 733p, 735p, 737p and 739p and the widths of the terminal-conductors 731n, 735n, and 739n are implemented to be larger than the widths of the other terminal-conductors in the circuit cell, whereby the speed performance of the NAND gate 700 is improved.

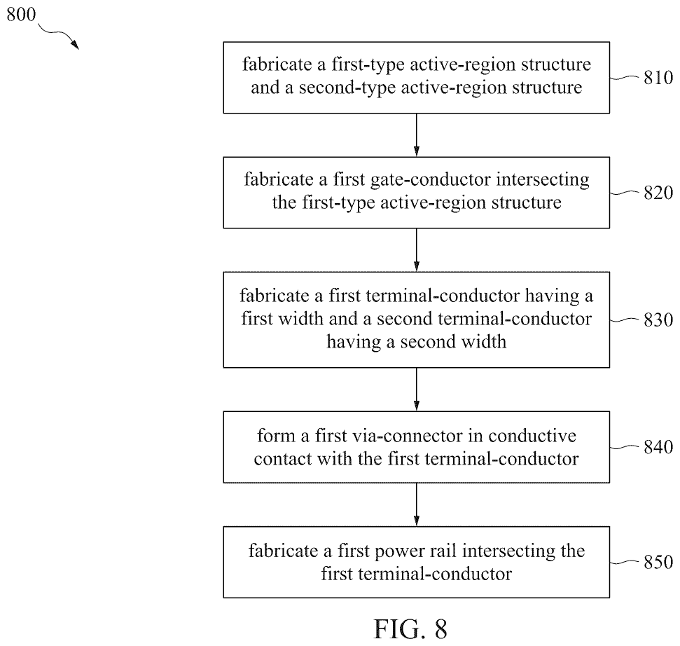

FIG. 8 is a flowchart of a method 800 of manufacturing an integrated circuit, in accordance with some embodiments. The sequence in which the operations of method 800 are depicted in FIG. 8 is for illustration only; the operations of method 800 are capable of being executed in sequences that differ from that depicted in FIG. 8. It is understood that additional operations may be performed before, during, and/or after the method 800 depicted in FIG. 8, and that some other processes may only be briefly described herein.

In operation 810 of method 800, a first-type active-region structure and a second-type active-region structure are fabricated on a substrate. In the example embodiments as shown in FIGS. 4A-4B and FIGS. 5A-5B, the active-region structure 80p and the active-region structure 80n are fabricated on the substrate 20. Each of the active-region structure 80p and the active-region structure 80n extends in the X-direction. Examples of the active-region structures fabricated in operation 810 include fin structures, nano-sheet structures, and nano-wire structures.

In operation 820 of method 800, a first gate-conductor intersecting the first-type active-region structure is fabricated. In the example embodiment as shown in FIGS. 4A-4B, the gate-conductor 455 intersecting the active-region structure 80p is fabricated. In the example embodiment as shown in FIGS. 5A-5B, the gate-conductors 552, 554, 556, and 558 intersects the active-region structure 80p are fabricated.

In operation 830 of method 800, a first terminal-conductor having a first width and a second terminal-conductor having a second width are fabricated. The first width is larger than the second width by a predetermined amount. In the example embodiment as shown in FIGS. 4A-4B, the terminal-conductors 432 and 438p intersecting the active-region structure 80p are fabricated, and the width of the terminal-conductor 438p is larger than the width of the terminal-conductor 432. Each of the terminal-conductors 432 and 438p is adjacent to the gate-conductor 455. In the example embodiment as shown in FIGS. 5A-5B, the terminal-conductors 532p, 535p, and 538p intersecting the active-region structure 80p and the terminal-conductors 534 and 536 intersecting the active-region structure 80p are fabricated. Each of the terminal-conductors 532p, 535p, and 538p has a width that is larger than the width of any of the terminal-conductors 534 and 536.

In operation 840 of method 800, a first via-connector in conductive contact with the first terminal-conductor is formed. In the example embodiment as shown in FIG. 4A and 4C, a via-connector in conductive contact with the terminal-conductor 438p is formed at the intersection between the power rail 42 and the terminal-conductor 438p. In the example embodiment as shown in FIG. 5A and FIG. 5C, via-connectors in conductive contact with the terminal-conductors 532p, 535p, and 538p are fabricated at the corresponding intersection between the power rail 42 and the terminal-conductor the terminal-conductors 532p, 535p, and 538p.

In operation 850 of method 800, a first power rail intersecting the first terminal-conductor is fabricated and the first power rail is conductively connected to the first terminal-conductor through the first via-connector. In the example embodiment as shown in FIG. 4A and 4C, the power rail 42 intersects the terminal-conductor 438p and is fabricated and the power rail 42 is conductively connected to the terminal-conductor 438p through a via-connector. In the example embodiment as shown in in FIG. 5A and 5C, the power rail 42 intersects each of the terminal-conductors 532p, 535p, and 538p and is fabricated and the power rail 42 is conductively connected to each of the terminal-conductors 532p, 535p, and 538p through a corresponding via-connector.

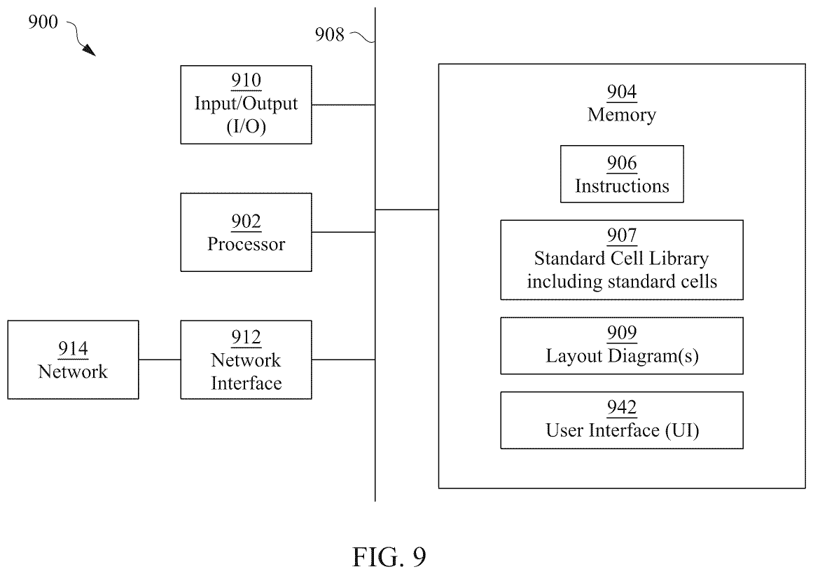

FIG. 9 is a block diagram of an electronic design automation (EDA) system 900 in accordance with some embodiments.

In some embodiments, EDA system 900 includes an APR system. Methods described herein of designing layout diagrams represent wire routing arrangements, in accordance with one or more embodiments, are implementable, for example, using EDA system 900, in accordance with some embodiments.

In some embodiments, EDA system 900 is a general purpose computing device including a hardware processor 902 and a non-transitory, computer-readable storage medium 904. Computer-readable storage medium 904, amongst other things, is encoded with, i.e., stores, computer program code 906, i.e., a set of executable instructions. Execution of instructions 906 by hardware processor 902 represents (at least in part) an EDA tool which implements a portion or all of the methods described herein in accordance with one or more embodiments (hereinafter, the noted processes and/or methods).

Processor 902 is electrically coupled to computer-readable storage medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable storage medium 904 are capable of connecting to external elements via network 914. Processor 902 is configured to execute computer program code 906 encoded in computer-readable storage medium 904 in order to cause EDA system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable storage medium 904 is an electronic, magnetic, optical, electromagnetic, infrared, and/or a semiconductor system (or apparatus or device). For example, computer-readable storage medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 904 includes a compact disk-read only memory (CD-ROM), a compact disk-read/write (CD-R/W), and/or a digital video disc (DVD).

In one or more embodiments, computer-readable storage medium 904 stores computer program code 906 configured to cause EDA system 900 (where such execution represents (at least in part) the EDA tool) to be usable for performing a portion or all of the noted processes and/or methods. In one or more embodiments, computer-readable storage medium 904 also stores information which facilitates performing a portion or all of the noted processes and/or methods. In one or more embodiments, computer-readable storage medium 904 stores library 907 of standard cells including such standard cells as disclosed herein. In one or more embodiments, computer-readable storage medium 904 stores one or more layout diagrams 909 corresponding to one or more layouts disclosed herein.

EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

EDA system 900 also includes network interface 912 coupled to processor 902. Network interface 912 allows EDA system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 900.

EDA system 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. EDA system 900 is configured to receive information related to a UI through I/O interface 910. The information is stored in computer-readable storage medium 904 as user interface (UI) 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

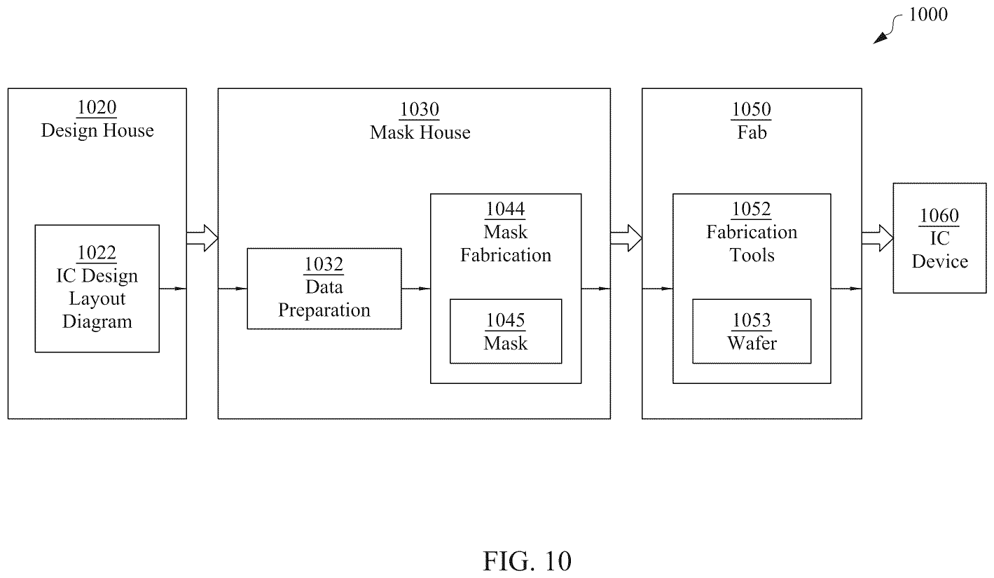

FIG. 10 is a block diagram of an integrated circuit (IC) manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using IC manufacturing system 1000.

In FIG. 10, IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in IC manufacturing system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns designed for an IC device 1060. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place and route. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (“RDF”). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The IC design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for limitations during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some embodiments, a device includes: a first power rail and a second power rail extending in a first direction and spaced apart in a second direction; a first active region and a second active region extending in the first direction, wherein: the first active region and the second active region are between the first power rail and the second power rail relative to the second direction, and the first active region and the second active region are spaced apart in the second direction; a first source/drain (S/D) conductor extending in the second direction, wherein: the first S/D conductor is conductively connected to both the first active region and the first power rail, and the first S/D conductor is between the first active region and the first power rail relative to a third direction perpendicular to the first and second directions; a second S/D conductor extending in the second direction, wherein: the second S/D conductor is at a same level as the first S/D conductor, the second S/D conductor is conductively connected to the first active region and is spaced apart in the second direction from the first power rail, and the first S/D conductor is wider than the second S/D conductor; and a first gate extending in the second direction between the first S/D conductor and the second S/D conductor, wherein: the first gate, the first S/D conductor, and the second S/D conductor are components of a first transistor at the first active region.

In some embodiments, the device further includes: a via-connector connecting the first S/D conductor to the first power rail at an intersection between the first S/D conductor and the first power rail. In some embodiments, the device further includes: a third S/D conductor extending in the second direction, wherein: the third S/D conductor is conductively connected to both the second active region and the second power rail, and the first S/D conductor has a first width, the second S/D conductor has a second width, and a third width of the third S/D conductor is equal to the first width. In some embodiments, the third S/D conductor is aligned with the first S/D conductor along the second direction such that a virtual line extending in the second direction crosses both the third S/D conductor and the first S/D conductor. In some embodiments, the device further includes: a via-connector connecting the third S/D conductor to the second power rail at an intersection of the third S/D conductor with the second power rail. In some embodiments, the first gate is conductively connected to the second active region, and the first gate is adjacent to the third S/D conductor. In some embodiments, the device further includes: a second gate extending in the second direction and conductively connected to the second active region, wherein: the second gate is adjacent to the third S/D conductor. In some embodiments, the device further includes: a fourth S/D conductor extending in the second direction, wherein: the fourth S/D conductor is conductively connected to the second active region and is spaced apart in the second direction from the second power rail, and a fourth width of the fourth S/D conductor is equal to the second width. In some embodiments, the fourth S/D conductor has a same length along the second direction as the second S/D conductor. In some embodiments, the first S/D conductor has a first width, the second S/D conductor has a second width, and the first width is larger than the second width by at least 20%. In some embodiments, the first S/D conductor has a first width, the second S/D conductor has a second width, and the first width is larger than the second width by at least 10%.

In some embodiments, a device includes: a first conductor configured to provide a first supply voltage, the first conductor extending in a first direction; an active region spaced apart from the first conductor in a second direction perpendicular to the first direction; a first boundary isolation structure at a first side of the active region; a second boundary isolation structure at a second side of the active region; first and second gates between the first and second boundary isolation structures; and first, second, and third S/D conductors between the first and second boundary isolation structures, wherein: the second S/D conductor is between the first and third S/D conductors, the first and second gates are between the first and third S/D conductors, the second S/D conductor is between the first and second gates, the first, second, and third S/D conductors are conductively connected to the active region, the first and third S/D conductors are conductively connected to the first conductor, the second S/D conductor is spaced apart in the second direction from the first conductor, and the first and third S/D conductors have a first width W1 in the first direction, the second S/D conductor has a second width W2 in the first direction, and W1>W2.

In some embodiments, the first and second boundary isolation structures are at vertical boundaries of a circuit cell. In some embodiments, \frac{W1}{W2}\geq\ 1.1. In some embodiments, the first and third S/D conductors are transistor source conductors for respective first and second transistors. In some embodiments, the second S/D conductor is a common drain conductor of the first and second transistors.

In some embodiments, a device includes: a first active region extending in a first direction and a second active region extending in the first direction and spaced apart from the first active region in a second direction perpendicular to the first direction; a first dummy gate at a first side of the first and second active regions; a second dummy gate at a second side of the first and second active regions; first and second gates between the first and second dummy gates; and first, second, third, fourth, and fifth S/D conductors between the first and second dummy gates, wherein: the first and second active regions have different conductivity types, the first and second gates each extend over each of the first and second active regions, the first S/D conductor is conductively connected to the first and second active regions, the second S/D conductor is between the first and third S/D conductors, the first and second gates are between the first and third S/D conductors, the second S/D conductor is between the first and second gates, the first, second, and third S/D conductors are conductively connected to the first active region, the first, fourth, and fifth S/D conductors are conductively connected to the second active region, the second and fifth S/D conductors are configured to be connected to respective supply voltages, and the second and fifth S/D conductors have a first width W1 in the first direction, the first S/D conductor has a second width W2 in the first direction, and W1>W2.

In some embodiments, the third S/D conductor has a third width W3 in the first direction, and W1>W3. In some embodiments, W1>W3>W2. In some embodiments, the second S/D conductor is source conductor of a PMOS transistor, and the fifth S/D conductor is a source conductor of an NMOS transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first power rail and a second power rail extending in a first direction and spaced apart in a second direction;
a first active region and a second active region extending in the first direction, wherein:
the first active region and the second active region are between the first power rail and the second power rail relative to the second direction, and
the first active region and the second active region are spaced apart in the second direction;
a first source/drain (S/D) conductor extending in the second direction, wherein:
the first S/D conductor is conductively connected to both the first active region and the first power rail, and
the first S/D conductor is between the first active region and the first power rail relative to a third direction perpendicular to the first and second directions;
a second S/D conductor extending in the second direction, wherein:
the second S/D conductor is at a same level as the first S/D conductor,
the second S/D conductor is conductively connected to the first active region and is spaced apart in the second direction from the first power rail, and
the first S/D conductor is wider than the second S/D conductor; and
a first gate extending in the second direction between the first S/D conductor and the second S/D conductor, wherein:
the first gate, the first S/D conductor, and the second S/D conductor are components of a first transistor at the first active region.

2. The device of claim 1, further comprising:
a via-connector connecting the first S/D conductor to the first power rail at an intersection between the first S/D conductor and the first power rail.

3. The device of claim 1, further comprising:
a third S/D conductor extending in the second direction, wherein:
the third S/D conductor is conductively connected to both the second active region and the second power rail, and
the first S/D conductor has a first width, the second S/D conductor has a second width, and a third width of the third S/D conductor is equal to the first width.

4. The device of claim 3, wherein:
the third S/D conductor is aligned with the first S/D conductor along the second direction such that a virtual line extending in the second direction crosses both the third S/D conductor and the first S/D conductor.

5. The device of claim 3, further comprising:
a via-connector connecting the third S/D conductor to the second power rail at an intersection of the third S/D conductor with the second power rail.

6. The device of claim 3, wherein:
the first gate is conductively connected to the second active region, and the first gate is adjacent to the third S/D conductor.

7. The device of claim 3, further comprising:
a second gate extending in the second direction and conductively connected to the second active region, wherein:
the second gate is adjacent to the third S/D conductor.

8. The device of claim 7, further comprising:
a fourth S/D conductor extending in the second direction, wherein:
the fourth S/D conductor is conductively connected to the second active region and is spaced apart in the second direction from the second power rail, and
a fourth width of the fourth S/D conductor is equal to the second width.

9. The device of claim 8, wherein:
the fourth S/D conductor has a same length along the second direction as the second S/D conductor.

10. The device of claim 1, wherein:
the first S/D conductor has a first width, the second S/D conductor has a second width, and the first width is larger than the second width by at least 20%.

11. The device of claim 1, wherein:
the first S/D conductor has a first width, the second S/D conductor has a second width, and the first width is larger than the second width by at least 10%.

12. A device comprising:
a first conductor configured to provide a first supply voltage, the first conductor extending in a first direction;
an active region spaced apart from the first conductor in a second direction perpendicular to the first direction;
a first boundary isolation structure at a first side of the active region;
a second boundary isolation structure at a second side of the active region;
first and second gates between the first and second boundary isolation structures; and
first, second, and third S/D conductors between the first and second boundary isolation structures, wherein:
the second S/D conductor is between the first and third S/D conductors,
the first and second gates are between the first and third S/D conductors,
the second S/D conductor is between the first and second gates,
the first, second, and third S/D conductors are conductively connected to the active region,
the first and third S/D conductors are conductively connected to the first conductor,
the second S/D conductor is spaced apart in the second direction from the first conductor, and
the first and third S/D conductors have a first width W1 in the first direction, the second S/D conductor has a second width W2 in the first direction, and W1>W2.

13. The device of claim 12, wherein:
the first and second boundary isolation structures are at vertical boundaries of a circuit cell.

14. The device of claim 12, wherein:
$$\frac{W 1}{W 2} \geq 1.1 .$$

15. The device of claim 12, wherein:
the first and third S/D conductors are transistor source conductors for respective first and second transistors.

16. The device of claim 15, wherein:
the second S/D conductor is a common drain conductor of the first and second transistors.

17. A device comprising:
a first active region extending in a first direction and a second active region extending in the first direction and spaced apart from the first active region in a second direction perpendicular to the first direction;
a first dummy gate at a first side of the first and second active regions;
a second dummy gate at a second side of the first and second active regions;
first and second gates between the first and second dummy gates; and
first, second, third, fourth, and fifth S/D conductors between the first and second dummy gates, wherein:
the first and second active regions have different conductivity types,
the first and second gates each extend over each of the first and second active regions,
the first S/D conductor is conductively connected to the first and second active regions,
the second S/D conductor is between the first and third S/D conductors,
the first and second gates are between the first and third S/D conductors,
the second S/D conductor is between the first and second gates,
the first, second, and third S/D conductors are conductively connected to the first active region,
the first, fourth, and fifth S/D conductors are conductively connected to the second active region,
the second and fifth S/D conductors are configured to be connected to respective supply voltages, and
the second and fifth S/D conductors have a first width W1 in the first direction, the first S/D conductor has a second width W2 in the first direction, and W1>W2.

18. The device of claim 17, wherein:
the third S/D conductor has a third width W3 in the first direction, and W1>W3.

19. The device of claim 18, wherein:
$$W 1 > W 3 > W 2.$$

20. The device of claim 19, wherein:
the second S/D conductor is source conductor of a PMOS transistor, and
the fifth S/D conductor is a source conductor of an NMOS transistor.
